(19) United States
(12) Patent Application Publication
(10) Pub. No.: US 2021/0151395 A1
(43) Pub. Date: May 20, 2021

(54) PACKAGE STRUCTURE WITH INTEGRATED ANTENNA, PACKAGE STRUCTURE ARRAY, AND MANUFACTURING METHOD THEREOF

(71) Applicant: SOCLE TECHNOLOGY CORP., Hsinchu (TW)

(72) Inventors: CHING-YU NI, New Taipei (TW); HSIANG-HUA LU, New Taipei (TW)

(21) Appl. No.: 17/038,088

(22) Filed: Sep. 30, 2020

(30) Foreign Application Priority Data
Nov. 19, 2019 (CN) 201911136104.4

(51) Int. Cl. H01L 23/66; H01L 23/31; H01L 23/498; H01L 23/00; H01P 3/00; H01L 21/48; H01L 21/56; H01Q 1/48; H01Q 1/22; H01Q 21/06; H01Q 15/14

(52) U.S. Cl. CPC H01L 23/66; H01L 2223/6627; H01L 23/49822; H01L 23/49838; H01L 24/16; H01P 3/003; H01L 21/4853; H01L 21/4857; H01L 21/565; H01Q 1/48; H01Q 1/2283; H01Q 21/065; H01Q 15/141; H01L 2224/16227; H01L 2223/6677; H01L 23/3128

(57) ABSTRACT

A package structure includes a first substrate, a first redistribution layer, a second substrate, a carrier chip, a first package, and a patch antenna. The first substrate is grooved for receiving the first redistribution layer. The first redistribution layer is provided with a reflector. The second substrate located on a side of the first substrate has a second redistribution layer which is electrically connected to the first redistribution layer. The carrier chip is on the second substrate and electrically connected to the second redistribution layer. The first package encases the first redistribution layer, the second redistribution layer, the second substrate, and the carrier chip. The patch antenna is on a side of the first package away from the first substrate. A packaged structure array and a manufacturing method thereof are further disclosed.

### FIELD

The subject matter relates to semiconductor packages, and in particular to a package structure that includes an antenna, a package structure array, and a manufacturing method thereof.

### BACKGROUND

In an integrated circuit package, integration density can be increased by reducing sizes of components and elements. With an antenna being an indispensable component in a radio frequency (RF) front-end system, the antenna should be integrated and packaged in the RF front-end for increased miniaturization.

### BRIEF DESCRIPTION OF THE DRAWINGS

Implementations of the present technology will now be described, by way of embodiments, with reference to the attached figures.

FIG. 1 is a diagrammatic view of an embodiment of a package structure.

FIG. 2 is a diagrammatic view of an embodiment of a package structure array.

### DETAILED DESCRIPTION

Implementations of the disclosure will now be described, by way of embodiments only, with reference to the drawings. The disclosure is illustrative only, and changes may be made in the detail within the principles of the present disclosure. It will, therefore, be appreciated that the embodiments may be modified within the scope of the claims.

Unless otherwise defined, all technical terms used herein have the same meaning as commonly understood by one of ordinary skill in the art. The technical terms used herein are to provide a thorough understanding of the embodiments described herein, but are not to be considered as limiting the scope of the embodiments.

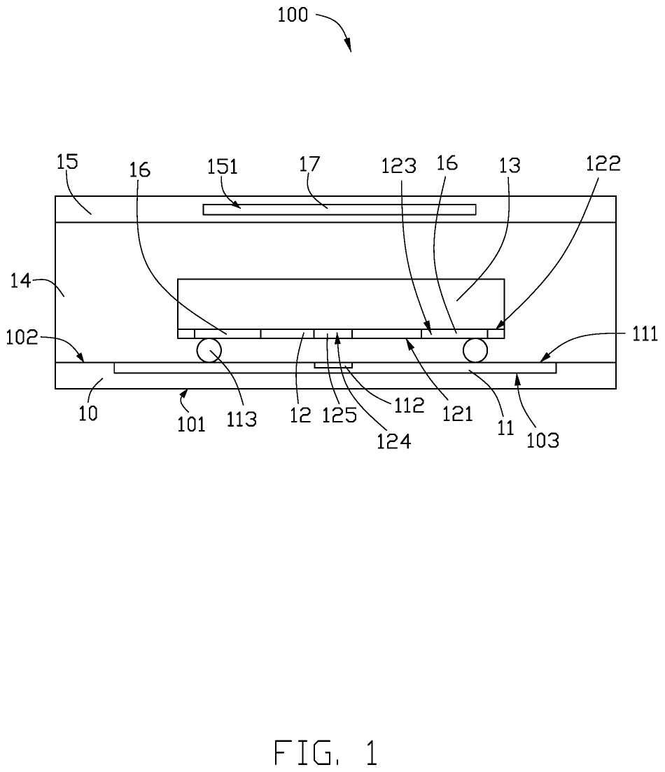

FIG. 1 illustrates an embodiment of a first package structure 100. The first package structure 100 includes a first substrate 10, a first redistribution layer 11, a second redistribution layer 16, a second substrate 12, a carrier chip 13, a first package 14, and a patch antenna 17.

The first substrate 10 provides support. The first substrate 10 includes a first surface 101, and a second surface 102 opposite to the first surface 101. The first substrate 10 may be made of ceramic, glass, semiconductor, polymer, etc. In this embodiment, the first substrate 10 is made of polyimide (PI).

The first substrate 10 defines a first groove 103 on the second surface 102, and the first redistribution layer 11 is built in the first groove 103. The first redistribution layer 11 includes a first outer surface 111, which is exposed in the first groove 103. The first outer surface 111 is flush with the second surface 102 to reduce a thickness of the first package structure 100. The first redistribution layer 11 may be a single-layer or a multi-layer structure. The first redistribution layer 11 may be made of dielectric material and/or conductive material, and is formed in the first groove 103 by deposition, damascene, electroplating, or electroless plating.

A reflector 112 is disposed in the first redistribution layer 11 and reflects signals from active circuits. The reflector 112 may be made of metal, metal alloys, or other materials suitable for reflecting signals, such as aluminum, copper, tungsten, nickel, other metals, or any combinations thereof.

The first outer surface 111 is provided with a first connecting element 113 which protrudes beyond the first outer surface 111. The first connecting element 113 is made of conductive materials, such as aluminum, copper, tungsten, nickel, other metals, or any combinations thereof. The first connecting element 113 may be a metal pad, a bolt, a conductive post, a solder ball, or other element which functions as an electrical connection. The first connecting element 113 electrically connects the first redistribution layer 11 and the second redistribution layer 16. In the embodiment, the first connecting element 113 is a solder ball.

The second substrate 12 is disposed on a side of the first connecting element 113 away from the first redistribution layer 11. The second substrate 12 provides supports. The second substrate 12 includes a third surface 121 and a fourth surface 122 opposite to the third surface 121. The fourth surface 122 is disposed away from the first redistribution layer 11. The second substrate 12 may be made of ceramic, glass, semiconductor, polymer, etc.

The second redistribution layer 16 is built in the second substrate 12. The second redistribution layer 16 may be a single-layer or a multi-layer structure. The second redistribution layer 16 may be made of dielectric material and/or conductive material, and the second redistribution layer 16 may be formed in the second substrate 12 by deposition, damascene, electroplating, or electroless plating. The second redistribution layer 16 provides grounding.

The second substrate 12 defines a first through hole 123, which passes through the third surface 121 and the fourth surface 122. The second redistribution layer 16 is built in the first through hole 123 and connected to the first connecting element 113, so that the first redistribution layer 11 is electrically connected to the second redistribution layer 16. The second redistribution layer 16 built in the second substrate 12 reduces the thickness of the first package structure 100.

The second substrate 12 defines a second through hole 124 which passes through the third surface 121 and the fourth surface 122. The second through hole 124 is disposed between the second redistribution layers 16. A coplanar waveguide (CPW) 125 is formed in the second through hole 124.

The fourth surface 122 is further provided with the carrier chip 13, which abuts the fourth surface 122 and is electrically connected to the second redistribution layer 16.

The first package 14 is disposed on the second surface 102 of the first substrate 10. The first package 14 encases the first redistribution layer 11, the first connecting element 113, the second redistribution layer 16, the second substrate 12, and the carrier chip 13. The first package 14 is made of non-conductive material which includes one or more of EMC (epoxy molding compound), ABS (acrylonitrile-butadiene-styrene), PC (polycarbonate), PET (polyethylene terephthalate), and other injection molding materials.

A third substrate 15 is disposed on a side of the first package 14 away from the first substrate 10. The third substrate 15 provides support. The third substrate 15 may be made of ceramic, glass, semiconductor, polymer, etc.

The third substrate 15 has a closed second groove 151 therein. The patch antenna 17 is built in the second groove 151.

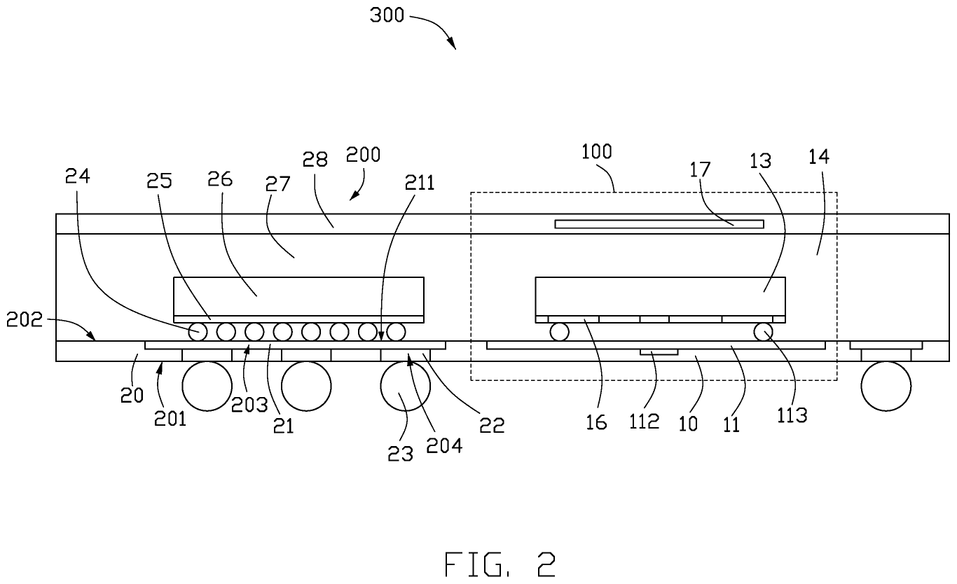

FIG. 2 illustrates an embodiment of a package structure array 300. The package structure array 300 includes at least one first package structure 100 and a second package structure 200. The second package structure 200 is electrically connected to each of the at least one first package structure 100.

Referring to FIGS. 1 and 2, the second package structure 200 includes a fourth substrate 20. The fourth substrate 20 provides support. The fourth substrate 20 and the first substrate 10 may be formed as an integral unit. The fourth substrate 20 may be made of ceramic, glass, semiconductor, polymer, etc. The fourth substrate 20 includes a fifth surface 201 and a sixth surface 202 parallel to the first surface 101 and the second surface 102.

The fourth substrate 20 defines a third groove 203 on the sixth surface 202. A third redistribution layer 21 is built in the third groove 203. The third redistribution layer 21 includes a second outer surface 211 which is exposed in the third groove 203 and flush with the sixth surface 202.

The third redistribution layer 21 may be a single-layer or a multi-layer structure. The third redistribution layer 21 may be made of dielectric material and/or conductive material, and is formed in the third groove 203 by process such as deposition, damascene, electroplating, or electroless plating.

Furthermore, a first contacting element 22 is disposed on the fifth surface 201 and electrically connected to the third redistribution layer 21. The fourth substrate 20 defines a third through hole 204, and the third through hole 204 communicates with the third groove 203. The first contacting element 22 is disposed in the third through hole 204, so that the third redistribution layer 21 is electrically connected to the first contacting element 22. Furthermore, the fourth substrate 20 defines a plurality of the third through holes 204.

The first contacting element 22 is provided with a second connecting element 23. The second connecting element 23 is made of conductive materials, such as copper, aluminum, tungsten, gold, silver, nickel, or alloys thereof. The second connecting element 23 may be a metal pad, a bolt, a conductive post, a solder ball, or other element which functions as an electrical connection. In the embodiment, the second connecting element 23 is a solder ball array.

The second outer surface 211 is provided with a third connecting element 24 which protrudes beyond the second outer surface 211. The third connecting element 24 is made of conductive materials, such as copper, aluminum, tungsten, gold, silver, nickel, or alloys thereof. The third connecting element 24 may be a metal pad, a bolt, a conductive post, a solder ball, or other element which functions as an electrical connection. In the embodiment, the third connecting element 24 is a solder ball.

The third connecting element 24 is provided with a second contacting element 25 on a side away from the third redistribution layer 21. The second contacting element 25 is made of conductive materials, such as copper, aluminum, tungsten, gold, silver, nickel, or alloys thereof. The second contacting element 25 may be formed by electroplating or sputtering.

The second package structure 200 further includes a radio frequency chip 26. The radio frequency chip 26 is disposed on a surface of the second contacting element 25 away from the third redistribution layer 21. The radio frequency chip 26 is electrically connected to the third redistribution layer 21 via the third connecting element 24 and the second contacting element 25.

The second package structure 200 further includes a second package 27. The second package 27 is disposed on the fourth substrate 20, and abuts the first package 14. The second package 27 and the first package 14 may be formed as an integral unit. The second package 27 encases the third redistribution layer 21, the third connecting element 24, the second contacting element 25, and the radio frequency chip 26. The second package 27 is made of non-conductive material which includes one or more of EMC (epoxy molding compound), ABS (acrylonitrile-butadiene-styrene), PC (polycarbonate), PET (polyethylene terephthalate), and other injection molding materials.

The second package structure 200 further includes a fifth substrate 28. The fifth substrate 28 is disposed on a surface of the second package 27 away from the fourth substrate 20, the third substrate 15 of the first package structure 100 extending along a surface of the second package 27 away from the third redistribution layer 21 forms the fifth substrate 28. The third substrate 15 and the fifth substrate 28 may be formed as an integral unit.

In one embodiment, a manufacturing method of the first package structure 100 is disclosed. The manufacturing method includes steps as follows:

A first substrate 10 is provided. The first substrate 10 includes a first surface 101, and a second surface 102 opposite to the first surface 101. The first substrate 10 may be made of ceramic, glass, semiconductor, polymer, etc. For example, the first substrate 10 is made of polyimide. The first substrate 10 defines a first groove 103 on the second surface 102.

A first redistribution layer 11 is formed in the first groove 103. The first redistribution layer 11 may be a single-layer or a multi-layer structure. The first redistribution layer 11 may be made of dielectric material and/or conductive material, and is formed in the first groove 103 by deposition, damascene, electroplating, or electroless plating. A first outer surface 111 of the first redistribution layer 11 and the second surface 102 are on a same plane.

The first redistribution layer 11 is provided with a reflector 112 therein. The reflector 112 may be made of metals, metal alloys, or other materials suitable for reflecting signals, such as aluminum, copper, tungsten, nickel, other metals, or any combinations thereof.

A carrier chip 13 is provided. The carrier chip 13 is electrically connected to the first redistribution layer 11.

The carrier chip 13 is provided with a second substrate 12 on a surface facing the first redistribution layer 11. The second substrate 12 provides support, and includes a third surface 121 and a fourth surface 122 opposite to the third surface 121. The fourth surface 122 is disposed away from the first redistribution layer 11. The second substrate 12 may be made of ceramic, glass, semiconductor, polymer, etc.

A second redistribution layer 16 is disposed on the second substrate 12. The second redistribution layer 16 provides grounding. In the embodiment, the second substrate 12 has a first through hole 123 for connecting the third surface 121 and the fourth surface 122. The second redistribution layer 16 is built in the first through hole 123 of the second substrate 12, and connected to a first connecting element 113, so that the first redistribution layer 11 is electrically connected to the second redistribution layer 16. The second substrate 12 defines a second through hole 124 which passes through the third surface 121 and the fourth surface 122. The second through hole 124 is disposed between the second redistribution layers 16. A CPW 125 is formed in the second through hole 124.

The first redistribution layer 11, the first connecting element 113, the second redistribution layer 16, the second substrate 12, and the carrier chip 13 are packaged. Specifically, a first package 14 is disposed on the first substrate 10, and encases the first redistribution layer 11, the first connecting element 113, the second redistribution layer 16, the second substrate 12, and the carrier chip 13.

The first package 14 is made of non-conductive material which includes one or more of EMC (epoxy molding compound), ABS (acrylonitrile-butadiene-styrene), PC (polycarbonate), PET (polyethylene terephthalate), and other injection molding materials.

A third substrate 15 is provided on a side of the first package 14 away from the first substrate 10. The third substrate 15 provides support. The third substrate 15 may be made of ceramic, glass, semiconductor, polymer, etc.

The third substrate 15 has a closed second groove 151 therein. A patch antenna 17 is built in the second groove 151.

In the first package structure 100, each layer structure is stacked to form the first package structure 100, and the first redistribution layer 11 and the second redistribution layer 16 are respectively disposed in the first substrate 10 and the second substrate 12 to reduce the thickness of the first package structure 100, thereby achieving high integration of the first package structure 100.

Even though information and advantages of the present embodiments have been set forth in the foregoing description, together with details of the structures and functions of the present embodiments, the disclosure is illustrative only. Changes may be made in detail, especially in matters of shape, size, and arrangement of parts within the principles of the present exemplary embodiments, to the full extent indicated by the plain meaning of the terms in which the appended claims are expressed.

What is claimed is:

1. A package structure comprising:
a first substrate defining a first groove;
a first redistribution layer built in the first groove;
a reflector disposed in the first redistribution layer;
a second substrate disposed on a side of the first substrate with the first redistribution layer;
a second redistribution layer disposed in the second substrate and electrically connected to the first redistribution layer, the second redistribution layer being configured for grounding;
a carrier chip disposed on the second substrate and electrically connected to the second redistribution layer;
a first package encasing the first redistribution layer, the second redistribution layer, the second substrate, and the carrier chip; and
a patch antenna disposed on a side of the first package away from the first substrate.

2. The package structure of claim 1, wherein the second substrate defines a first through hole, the second redistribution layer is built in the first through hole, the first redistribution layer is electrically connected to the second redistribution layer via a first connecting element.

3. The package structure of claim 2, wherein the first connecting element is a metal pad, a bolt, a conductive post, or a solder ball.

4. The package structure of claim 1, further comprising a third substrate, wherein the third substrate is disposed on the side of the first package away from the first substrate, the third substrate defines a second groove, the patch antenna is built in the second groove.

5. The package structure of claim 1, further comprising a coplanar waveguide, wherein the second substrate defines a second through hole, the coplanar waveguide is built in the second through hole.

6. A package structure array comprising:
a first package structure comprising:
a first substrate defining a first groove on a surface,
a first redistribution layer built in the first groove and provided with a reflector,
a second substrate provided with a second redistribution layer, the second redistribution layer being electrically connected to the first redistribution layer and configured for grounding,
a carrier chip electrically connected to the second redistribution layer,
a first package encasing the first redistribution layer, the second redistribution layer, the second substrate, and the carrier chip, and
a patch antenna disposed on a side of the first package away from the first substrate; and
a second package structure electrically connected to the first package structure;
wherein the second package structure comprises a radio frequency chip, the radio frequency chip is electrically connected to the first package structure.

7. The package structure array of claim 6, wherein the second package structure further comprises a fourth substrate and a third redistribution layer, the fourth substrate and the first substrate are on a same plane, the fourth substrate defines a third groove, the third redistribution layer is built in the third groove and electrically connected to the radio frequency chip.

8. The package structure array of claim 7, wherein the fourth substrate further defines a third through hole on a surface away from the third groove, and the third through hole communicates with the third groove; the third through hole is provided with a first contacting element therein, the first contacting element connects the third redistribution layer and a second connecting element.

9. The package structure array of claim 8, wherein the second connecting element is a metal pad, a bolt, a conductive post, or a solder ball.

10. The package structure array of claim 8, wherein the radio frequency chip is electrically connected to the third redistribution layer via a third connecting element and a second contacting element, the third connecting element is disposed between the radio frequency chip and the third redistribution layer, the second contacting element is disposed between the third connecting element and the radio frequency chip.

11. The package structure array of claim 10, wherein the third connecting element is a metal pad, a bolt, a conductive post, or a solder ball.

12. The package structure array of claim 10, wherein the second package structure further comprises a second package, the second package is disposed on the fourth substrate and encases the third redistribution layer, the third connecting element, the second contacting element, and the radio frequency chip.

13. The package structure array of claim 6, wherein the second substrate defines a first through hole, the second redistribution layer is built in the first through hole, the first redistribution layer is electrically connected to the second redistribution layer via a first connecting element.

14. The package structure array of claim 13, wherein the first connecting element is a metal pad, a bolt, a conductive post, or a solder ball.

15. The package structure array of claim 6, wherein the first package structure further comprises a third substrate, wherein the third substrate is disposed on the side of the first package away from the first substrate, the third substrate defines a second groove, the patch antenna is built in the second groove.

16. The package structure array of claim 6, wherein the first package structure further comprises a coplanar waveguide, the second substrate defines a second through hole, the coplanar waveguide is built in the second through hole.

17. A manufacturing method of a package structure comprising:
providing a first substrate, the first substrate defining a first groove;
forming a first redistribution layer into the first groove, the first redistribution layer being provided with a reflector therein;
forming a carrier chip on the first redistribution layer, the carrier chip being electrically connected to the first redistribution layer via a first connecting element forming a second redistribution layer between the carrier chip and the first redistribution layer;
encapsulating the first redistribution layer, the first connecting element, the second redistribution layer, and the carrier chip to form a first package; and
forming a patch antenna on a side of the first package away from the first substrate.
